(19) United States
(12) Patent Application Publication
(10) Pub. No.: US 2026/0157044 A1
(43) Pub. Date: Jun. 4, 2026

(54) Display Device and Display Panel

(71) Applicant: LG Display Co., Ltd., Seoul (KR)

(72) Inventors: EunHye Lee, Paju-si (KR); GiSang Hong, Paju-si (KR); Hyeonchul Im, Paju-si (KR)

(21) Appl. No.: 19/335,220

(22) Filed: Sep. 22, 2025

(30) Foreign Application Priority Data
Dec. 2, 2024 (KR) 10-2024-0176738

(51) Int. Cl. H10K 59/122; H10K 59/80; H10K 102/00

(52) U.S. Cl. CPC H10K 59/122; H10K 59/8731; H10K 2102/351

(57) ABSTRACT

Embodiments of the present disclosure may provide a display device including a display panel including a display area in which a plurality of subpixels are disposed, and a driving circuit configured to drive the display panel, wherein the display area includes a first bank defining an emission area of the plurality of subpixels, and a second bank including multi-pattern areas of different heights on the first bank; and the display panel.

### CROSS REFERENCE TO RELATED APPLICATION

This application claims priority under 35 U.S.C. § 119(a) to the Republic of Korea Patent Application No. 10-2024-0176738, filed on Dec. 2, 2024, the entire contents of which are hereby expressly incorporated by reference into the present application.

### TECHNICAL FIELD

Embodiments of the present disclosure relate to a display device and a display panel, and more specifically, to a display device and a display panel capable of improving an encapsulation function of a light emitting element.

### BACKGROUND

As examples of display devices for displaying images using digital data, there are liquid crystal displays (LCD) using liquid crystals and organic light emitting displays (OLED) using organic light emitting diodes.

Among display devices, the organic light emitting display device utilizes self-luminous light emitting diodes, which provide fast response speeds and have advantages in contrast ratio, luminous efficiency, brightness, and viewing angle. In this case, the light emitting diodes can be implemented as inorganic or organic materials.

The organic light emitting display device may include organic light emitting diodes arranged in each of a plurality of subpixels disposed on a display panel and may control the brightness of each subpixel by controlling a voltage flowing to the organic light emitting diodes to emit light, thereby displaying images.

In this case, an encapsulation layer may be disposed on the top of the display panel to prevent external moisture or oxygen from penetrating into the light emitting element.

However, as a display panel becomes thinner, the thickness of the encapsulation layer is also becoming thinner, and as a result, there may occur a problem in which the encapsulation layer is not properly formed on the surface of the light emitting element.

### SUMMARY

Accordingly, the inventors of the present disclosure invented a display device and a display panel capable of forming an encapsulation layer so as to seal the surface of a light emitting element even when the thickness of the encapsulation layer is reduced.

Embodiments of the present disclosure may provide a display device and a display panel in which an encapsulation layer bank is formed in a multi-pattern structure so that the encapsulation layer can be effectively applied to a surface of a light emitting element.

Embodiments of the present disclosure may provide a display device and a display panel in which a valley pattern is formed in some area of a bank so that the encapsulation layer can easily spread to the surface of the light emitting element.

Embodiments of the present disclosure may provide a display device and a display panel in which a convex portion is formed at a position where the concave portions of the bank overlap, thereby allowing the encapsulation layer to easily spread onto the surface of the light emitting element.

Embodiments of the present disclosure may provide a display device including a display panel including a display area in which a plurality of subpixels are disposed, and a driving circuit configured to drive the display panel, wherein the display area includes a first bank defining an emission area of the plurality of subpixels, and a second bank including multi-pattern areas of different thicknesses on the first bank.

Embodiments of the present disclosure may provide a display panel including a plurality of subpixels, a first bank defining an emission area of the plurality of subpixels, and a second bank including multi-pattern areas of different thicknesses on the first bank.

According to embodiments of the present disclosure, it is possible to manufacture a lightweight display device by forming an encapsulation layer to seal the surface of a light emitting element even when the thickness of the encapsulation layer is reduced.

According to embodiments of the present disclosure, it is possible to provide an effect in which the encapsulation layer can be effectively applied to the surface of the light emitting element by forming the bank into a multi-pattern structure.

According to embodiments of the present disclosure, it is possible to provide an effect in which a valley pattern is formed in some area of a bank so that the encapsulation layer can easily spread to the surface of the light emitting element.

According to embodiments of the present disclosure, it is possible to provide an effect in which a convex portion is formed at a position where the valley patterns of the bank overlap, thereby allowing the encapsulation layer to easily spread onto the surface of the light emitting element.

### BRIEF DESCRIPTION OF THE DRAWINGS

FIG. 1 schematically illustrates a display device according to embodiments of the present disclosure.

FIG. 2 illustrates an equivalent circuit of a subpixel in a display panel according to embodiments of the present disclosure as an example.

FIG. 3 illustrates a cross-section of a display area in a display panel according to embodiments of the present disclosure.

FIG. 4 is a cross-sectional photograph of an encapsulation layer formed on an upper portion of a bank in a display device.

FIG. 5 is a plan view of a display device according to embodiments of the present disclosure in which a bank located around an emission area is formed with a double pattern structure.

FIG. 6 is a cross-sectional view of a subpixel including a bank with a double pattern structure in a display device according to embodiments of the present disclosure, taken along the A-A′ direction.

FIG. 7 is a plan view illustrating a bank structure including a valley pattern between subpixels in a display device according to embodiments of the present disclosure.

FIG. 8 is a cross-sectional view of a bank structure including a valley pattern in a display device according to embodiments of the present disclosure taken along the B-B′ direction.

FIG. 9 is a cross-sectional view of a bank structure including a valley pattern in a display device according to embodiments of the present disclosure, taken along the C-C′ direction.

FIG. 10 is a plan view illustrating a case in which a valley pattern of a second bank extends only to a part of an area between subpixels in a display device according to embodiments of the present disclosure.

FIG. 11 is a plan view illustrating a bank structure including a double pattern positioned around an emission area and a valley pattern between subpixels in a display device according to embodiments of the present disclosure.

FIG. 12 is a plan view illustrating a bank structure including a convex portion between subpixels in a display device according to embodiments of the present disclosure.

FIG. 13 is a cross-sectional view of a bank structure including a convex portion in a display device according to embodiments of the present disclosure, taken along the D-D′ direction.

FIG. 14 is a cross-sectional view of a bank structure including a convex portion in a display device according to embodiments of the present disclosure, taken along the E-E′ direction.

### DETAILED DESCRIPTION

Hereinafter, some embodiments of the present disclosure will be described in detail with reference to exemplary drawings. In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components t

be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Hereinafter, various embodiments of the present disclosure will be described in detail with reference to the accompanying drawings.

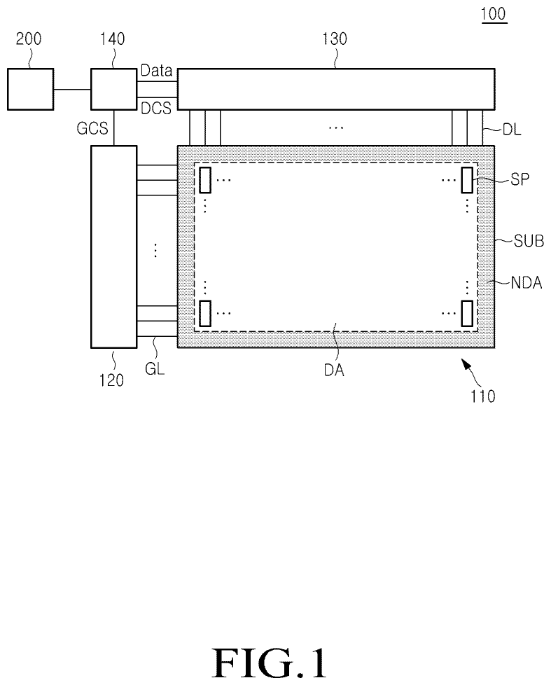

FIG. 1 schematically illustrates a display device according to embodiments of the present disclosure.

Referring to FIG. 1, the display device 100 according to the embodiments of the present disclosure may include a display panel 110 and a display driving circuit for driving the display panel 110.

The display panel 110 may include a display area DA where an image is displayed and a non-display area NDA where an image is not displayed. The non-display area NDA may also be referred to as a bezel area.

The display panel 110 may include a plurality of subpixels SP for displaying an image. For example, a plurality of subpixels SP may be arranged in the display area DA. In some cases, at least one subpixel SP may be arranged in the non-display area NDA. At least one subpixel SP arranged in the non-display area NDA may also be referred to as a dummy subpixel.

The display panel 110 may include a plurality of signal lines for driving a plurality of subpixels SP. For example, the plurality of signal lines may include a plurality of data lines DL and a plurality of gate lines GL. The signal lines may further include a plurality of data lines DL and a plurality of gate lines GL and other signal lines, depending on the structure of the subpixel SP. For example, the other signal lines may include a driving voltage line and a reference voltage line.

The plurality of data lines DL and the plurality of gate lines GL may intersect each other. Each of the plurality of data lines DL may be arranged so as to be extended in a first direction. Each of the plurality of gate lines GL may be arranged so as to be extended in a second direction. Here, the first direction may be a column direction and the second direction may be a row direction. In this disclosure, the column direction and the row direction are relative. For example, the column direction may be a vertical direction and the row direction may be a horizontal direction. For another example, the column direction may be a horizontal direction, and the row direction may be a vertical direction.

The driving circuit may include a data driving circuit 130 for driving a plurality of data lines DL and a gate driving circuit 120 for driving a plurality of gate lines GL. The driving circuit may further include a timing controller 140 for controlling the data driving circuit 130 and the gate driving circuit 120.

The data driving circuit 130 is a circuit for driving a plurality of data lines DL and may output a data signal (also called a data voltage) corresponding to an image signal to a plurality of data lines DL. The gate driving circuit 120 is a circuit for driving a plurality of gate lines GL, and may generate gate signals and output the gate signals to a plurality of gate lines GL. The gate signal may include one or more scan signals and a light emission signal.

The timing controller 140 may start a scan according to the timing implemented in each frame and control the data driving at an appropriate time according to the scan. The timing controller 140 may convert input image data input from the outside into a data signal format used by the data driving circuit 130, and supply the converted image data Data to the data driving circuit 130.

The timing controller 140 may receive display driving control signals from an external host system 200 along with input image data. For example, the display driving control signals may include a vertical synchronization signal, a horizontal synchronization signal, an input data enable signal, a clock signal, etc.

The timing controller 140 may generate a data driving control signal DCS and a gate driving control signal GCS based on the display driving control signals input from the host system 200. The timing controller 140 may control the driving operation and driving timing of the data driving circuit 130 by supplying the data driving control signal DCS to the data driving circuit 130. The timing controller 140 may control the driving operation and driving timing of the gate driving circuit 120 by supplying a gate driving control signal GCS to the gate driving circuit 120.

The data driving circuit 130 may include one or more source driving integrated circuits SDIC. Each source driving integrated circuit may include a shift register, a latch circuit, a digital to analog converter DAC, an output buffer, etc. Each source driving integrated circuit may further include an analog to digital converter ADC, depending on the case.

For example, each source driving integrated circuit may be connected to the display panel 110 in a tape-automated-bonding (TAB) manner, may be connected to a bonding pad of the display panel 110 in a chip-on-glass (COG) or chip-on-panel (COP) manner, or implemented in a chip-on-film (COF) manner and connected to the display panel 110.

The gate driving circuit 120 may output a gate signal of a turn-on level voltage or a gate signal of a turn-off level voltage under the control of the timing controller 140. The gate driving circuit 120 may sequentially drive a plurality of gate lines GL by sequentially supplying gate signals of a turn-on level voltage to a plurality of gate lines GL.

The gate driving circuit 120 may include one or more gate driving integrated circuits GDIC.

The gate driving circuit 120 may be connected to the display panel 110 in a tape-automated-bonding (TAB) manner, connected to a bonding pad of the display panel 110 in a chip-on-glass (COG) or chip-on-panel (COP) manner, or connected to the display panel 110 in a chip-on-film (COF) manner. Alternatively, the gate driving circuit 120 may be formed in a non-display area NDA of the display panel 110 in a gate-in-panel (GIP) type. The gate driving circuit 120 may be disposed on or connected to the substrate. That is, the gate driving circuit 120 may be disposed in a non-display area NDA of the substrate in the case of the gate-in-panel (GIP) type. The gate driving circuit 120 may be connected to the substrate if it is a chip-on-glass (COG) type or a chip-on-film (COF) type.

Meanwhile, at least one of the data driving circuit 130 and the gate driving circuit 120 may be disposed in the display area DA. For example, at least one of the data driving circuit 130 and the gate driving circuit 120 may be disposed so as not to overlap with the subpixels SP, or may be disposed so as to partially or completely overlap with the subpixels SP.

The data driving circuit 130 may be connected to one side (e.g., the upper side or the lower side) of the display panel 110. Depending on the driving method, the panel design method, etc., the data driving circuit 130 may be connected to both sides (e.g., the upper side and the lower side) of the display panel 110, or may be connected to two or more sides among the four sides of the display panel 110.

The gate driving circuit 120 may be connected to one side (e.g., left or right) of the display panel 110. Depending on the driving method, panel design method, etc., the gate driving circuit 120 may be connected to both sides (e.g., left and right) of the display panel 110, or may be connected to two or more of the four sides of the display panel 110.

The timing controller 140 may be implemented as a separate component from the data driving circuit 130, or may be implemented as an integrated circuit by being integrated with the data driving circuit 130. The timing controller 140 may be a controller used in a typical display technology, or may be a control device that can perform other control functions including the timing controller 140, or may be a circuit within the control device. The timing controller 140 may be implemented with various circuits or electronic components such as an integrated circuit (IC), a field programmable gate array (FPGA), an application specific integrated-circuit (ASIC), or a processor.

The timing controller 140 may be mounted on a printed circuit board or a flexible printed circuit, and may be electrically connected to the data driving circuit 130 and the gate driving circuit 120 through the printed circuit board or the flexible printed circuit. The timing controller 140 may transmit and receive signals with the data driving circuit 130 according to one or more predefined interfaces. Here, for example, the interface may include a low voltage differential signaling (LVDS) interface, an EPI interface, a serial peripheral (SP) interface, etc.

The display device 100 according to the embodiments of the present disclosure may be a self-luminous display device in which the display panel 110 emits light by itself. If the display device 100 according to embodiments of the present disclosure is a self-luminous display device, each of the plurality of subpixels SP may include a light emitting element. For example, the display device 100 according to embodiments of the present disclosure may be an organic light-emitting display device in which the light emitting element is implemented as an organic light-emitting diode (OLED). For another example, the display device 100 according to embodiments of the present disclosure may be an inorganic light-emitting display device in which the light emitting element is implemented as an inorganic-based light-emitting diode. For another example, the display device 100 according to embodiments of the present disclosure may be a quantum dot display device in which the light emitting element is implemented as a quantum dot, which is a semiconductor crystal that emits light by itself.

The display device 100 may include at least one source printed circuit board SPCB for circuit connection between a plurality of source driving integrated circuits SDIC and other devices, and a control printed circuit board CPCB for mounting control components and various electrical devices.

In this case, the other side of a source film SF on which the source driving integrated circuit SDIC is mounted may be connected to at least one source printed circuit board SPCB.

The timing controller 140 and a power management circuit (not shown) may be mounted on the control printed circuit board CPCB. The timing controller 140 may control the operation of the data driving circuit 130 and the gate driving circuit 120. The power management circuit may supply a driving voltage or current to the display panel 110, the data driving circuit 130, and the gate driving circuit 120, and may control the supplied voltage or current.

At least one source printed circuit board SPCB and a control printed circuit board CPCB may be connected to each other in a circuit manner through at least one connecting member, and the connecting member may be, for example, a flexible printed circuit (FPC), a flexible flat cable (FFC), etc. In addition, at least one source printed circuit board SPCB and a control printed circuit board CPCB may be implemented by being integrated into one printed circuit board.

In this case, each subpixel SP arranged on the display panel 110 in the display device 100 may be composed of a light emitting element and a circuit element such as a driving transistor for driving the light emitting element.

The type and number of circuit elements constituting each subpixel SP may be determined in various ways depending on the provided function and design method.

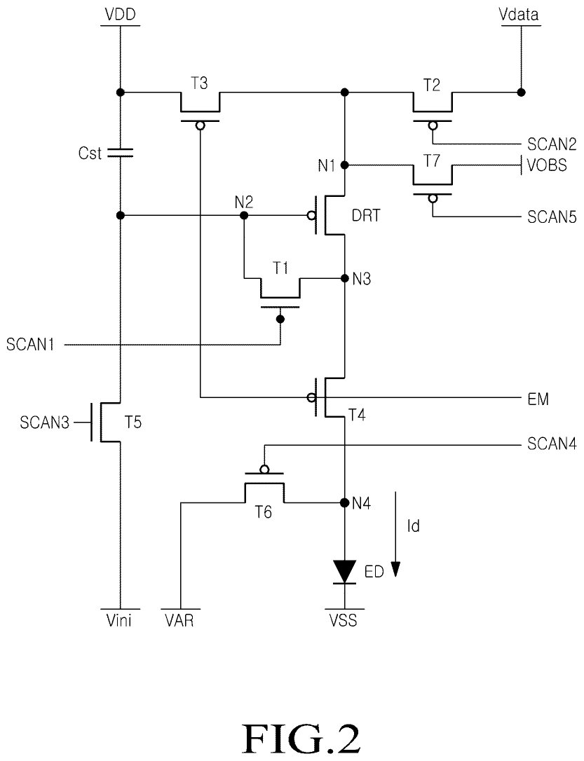

FIG. 2 illustrates an example of a subpixel circuit of a display device according to embodiments of the present disclosure.

Referring to FIG. 2, the subpixel SP of the display device 100 according to the embodiments of the present disclosure (FIG. 1) may include first to seventh switching transistors T1 to T7, a driving transistor DRT, a storage capacitor Cst, and a light emitting element ED.

Here, the light emitting element ED may be a self-luminous element that can emit light by itself, such as an organic light-emitting diode (OLED), for example.

In the subpixel SP according to the embodiments of the present disclosure, the second to fourth switching transistors T2 to T4, the sixth switching transistor T6, and the seventh switching transistor T7 may be P-type transistors. In addition, a first switching transistor T1 and a fifth switching transistor T5 may be N-type transistors.

The oxide transistor has a characteristic of relatively lower leakage current than the silicon transistor. Therefore, the driving transistor DRT or at least some of the switching transistors constituting the subpixel SP may be configured as oxide transistors.

For example, the driving transistor DRT and the first switching transistor T1 and the fifth switching transistor T5 connected to a gate electrode of the driving transistor DRT may be configured as oxide transistors.

In addition, the remaining switching transistors T2, T3, T4, T6, and T7 may be configured as low-temperature polysilicon transistors.

In this case, the subpixel SP of the display device 100 may be configured as the driving transistor DRT and a first group switching transistor T1 and T5 formed of oxide transistors, and a second group switching transistor T2, T3, T4, T6, and T7 formed of low-temperature polysilicon transistors.

A gate electrode of the first switching transistor T1 may be supplied with a first scan signal SCAN1. A second electrode (e.g., drain electrode) of the first switching transistor T1 may be connected to the gate electrode N2 of the driving transistor DRT. In addition, the first electrode (e.g., source electrode) of the first switching transistor T1 may be connected to the second electrode (e.g., drain electrode) N3 of the driving transistor DRT.

The first switching transistor T1 may be turned on by the first scan signal SCAN1 and form a current path between the gate electrode N2 of the driving transistor DRT and the second electrode (e.g., drain electrode) N3 by the storage capacitor Cst of which one side is connected to a high-potential driving voltage VDD.

A gate electrode of the second switching transistor T2 may be supplied with a second scan signal SCAN2. The first electrode (e.g., source electrode) of the second switching transistor T2 may be supplied with a data voltage Vdata. The second electrode (e.g., drain electrode) of the second switching transistor T2 may be connected to the first electrode (e.g., source electrode) N1 of the driving transistor DRT. The second switching transistor T2 may be turned on by the second scan signal SCAN2 and supply the data voltage Vdata to the first electrode (e.g., source electrode) N1 of the driving transistor DRT.

If the first switching transistor T1 is turned on, the data voltage Vdata may be supplied to the first electrode (e.g., source electrode) N1 of the driving transistor DRT through the second switching transistor T2, and the difference (Vdata−Vth) between the data voltage Vdata and a threshold voltage Vth of the driving transistor DRT may be sampled and supplied to the gate electrode N2 of the driving transistor DRT. Therefore, the first switching transistor T1 may be referred to as a sampling transistor, and the first scan signal SCAN1 may be referred to as a sampling scan signal.

A gate electrode of the third switching transistor T3 may be supplied with an emission signal EM. The first electrode (e.g., source electrode) of the third switching transistor T3 may be supplied with a high-potential driving voltage VDD. The second electrode (e.g., drain electrode) of the third switching transistor T3 may be connected to the first electrode (e.g., source electrode) N1 of the driving transistor DRT. The third switching transistor T3 may be turned on by the emission signal EM and supply a high-potential driving voltage VDD to the first electrode (e.g., source electrode) N1 of the driving transistor DRT.

A gate electrode of the fourth switching transistor T4 may be supplied with the emission signal EM. The first electrode (e.g., source electrode) of the fourth switching transistor T4 may be connected to the second electrode (e.g., drain electrode) N3 of the driving transistor DRT. The second electrode (e.g., drain electrode) of the fourth switching transistor T4 may be connected to an anode electrode N4 of a light emitting element ED. The fourth switching transistor T4 may be turned on by the light emission signal EM and supply a driving current Id to the anode electrode N4 of the light emitting element ED.

A gate electrode of the fifth switching transistor T5 may receive a third scan signal SCAN3. Here, the third scan signal SCAN3 may be a signal having a different phase from the first scan signal SCAN1 supplied to the subpixel SP at a different location. For example, if the first scan signal SCAN1 is applied to the n-th gate line, the third scan signal SCAN3 may use the first scan signal SCAN1[n-1] applied to the (n−1)-th gate line. That is, the third scan signal SCAN3 may use the first scan signal SCAN1 that changes the gate line GL depending on the phase in which the display panel 110 is driven.

A second electrode (e.g., drain electrode) of the fifth switching transistor T5 may be supplied with an initialization voltage Vini. The first electrode (e.g., source electrode) of the fifth switching transistor T5 may be connected to the gate electrode N2 of the driving transistor DRT and the storage capacitor Cst. The fifth switching transistor T5 may be turned on by the third scan signal SCAN3 and supply the initialization voltage Vini to the gate electrode N2 of the driving transistor DRT. Therefore, the fifth switching transistor T5 may be referred to as an initialization transistor, and the third scan signal SCAN3 may be referred to as an initialization scan signal.

A gate electrode of the sixth switching transistor T6 may be supplied with a fourth scan signal SCAN4. The first electrode (e.g., source electrode) of the sixth switching transistor T6 may be supplied with a reset voltage VAR. The second electrode (e.g., drain electrode) of the sixth switching transistor T6 may be connected to the anode electrode N4 of the light emitting element ED. The sixth switching transistor T6 may be turned on by the fourth scan signal SCAN4 and supply the reset voltage VAR to the anode electrode N4 of the light emitting element ED.

A gate electrode of the seventh switching transistor T7 may be supplied with a fifth scan signal SCAN5. The first electrode (e.g., source electrode) of the seventh switching transistor T7 may be supplied with a bias voltage VOBS. The second electrode (e.g., drain electrode) of the seventh switching transistor T7 may be connected to the first electrode (e.g., source electrode) N1 of the driving transistor DRT.

Here, the fifth scan signal SCAN5 may be a signal having a different phase from the third scan signal SCAN3 supplied to the subpixel SP at a different location. For example, if the third scan signal SCAN3 is applied to the n-th gate line, the fifth scan signal SCAN5 may be the third scan signal SCAN3 applied to the (n−1)-th gate line. That is, the fifth scan signal SCAN5 may utilize the third scan signal SCAN3 that changes the gate line GL depending on the phase in which the display panel 110 is driven.

Meanwhile, since the fifth scan signal SCAN5 is a signal for applying a bias voltage VOBS to the driving transistor DRT, it is desirable to distinguish the fifth scan signal SCAN5 from the second scan signal SCAN2 for applying a data voltage Vdata.

The gate electrode N2 of the driving transistor DRT may be connected to the second electrode (e.g., drain electrode) of the first switching transistor T1. The first electrode (e.g., source electrode) N1 of the driving transistor DRT may be connected to the second electrode (e.g., drain electrode) of the second switching transistor T2. The second electrode (e.g., drain electrode) N3 of the driving transistor DRT may be connected to the first electrode (e.g., source electrode) of the first switching transistor T1.

The driving transistor DRT may be turned on by the voltage difference between the gate electrode N2 and the first electrode (e.g., source electrode) N1, and the driving current Id may be applied to the light emitting element ED.

The first electrode (e.g., source electrode) and the second electrode (e.g., drain electrode) of the first switching transistor T1 may be respectively connected to the second electrode (e.g., drain electrode) N3 and the gate electrode N2 of the driving transistor DRT. In addition, if the first switching transistor T1 is turned on, there may be performed an operation of sampling and compensating the threshold voltage of the driving transistor DRT by the data voltage Vdata applied to the first electrode (e.g., source electrode) N1 of the driving transistor DRT.

One side of the storage capacitor Cst may be supplied with a high-potential driving voltage VDD, and the other side of the storage capacitor Cst may be connected to the gate electrode N2 of the driving transistor DRT. The storage capacitor Cst may store the voltage of the gate electrode N2 of the driving transistor DRT.

The anode electrode N4 of the light emitting element ED may be connected to the second electrode (e.g., drain electrode) of the fourth switching transistor T4 and the second electrode (e.g., drain electrode) of the sixth switching transistor T6. A low-potential base voltage VSS may be applied to a cathode electrode of the light emitting element ED.

The light emitting element ED may emit light with a predetermined brightness by the driving current Id flowing by the driving transistor DRT.

In this case, the initialization voltage Vini may be supplied to stabilize the change in the capacitance formed at the gate electrode N2 of the driving transistor DRT, and the reset voltage VAR may be supplied to reset the anode electrode N4 of the light emitting element ED.

If the fourth switching transistor T4, which is located between the anode electrode N4 of the light emitting element ED and the second electrode (e.g., drain electrode) N3 of the driving transistor DRT and is controlled by the emission signal EM, is turned off and a reset voltage VAR is supplied to the anode electrode N4 of the light emitting element ED, the anode electrode N4 of the light emitting element ED may be reset.

The sixth switching transistor T6 that supplies the reset voltage VAR may be connected to the anode electrode N4 of the light emitting element ED.

In this way, a subpixel SP composed of eight transistors DRT, T1, T2, T3, T4, T5, T6 and T7 and one storage capacitor Cst may be referred to as an 8T1C structure.

Here, the 8T1C structure is shown as an example among various structures of subpixel SP circuits, and the structure and number of transistors and capacitors constituting the subpixel SP may vary in various ways. Meanwhile, each of the plurality of subpixels SP may have the same structure, and some of the plurality of subpixels SP may have different structures.

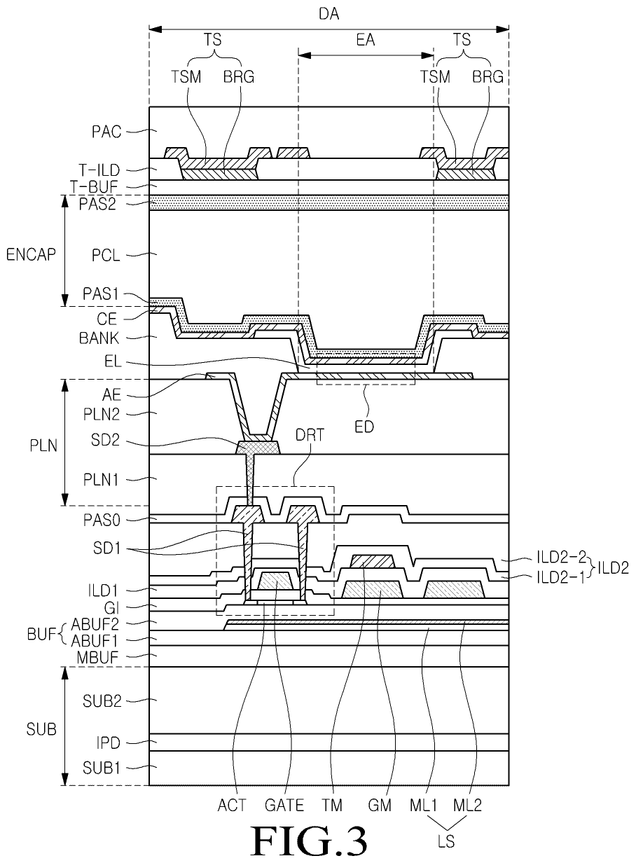

FIG. 3 illustrates an example of a cross-section of a display area in a display panel according to embodiments of the present disclosure.

Referring to FIG. 3, the display panel 110 according to embodiments of the present disclosure may include a substrate SUB, a driving transistor DRT, a planarization layer PLN, a light emitting element ED, an encapsulation layer ENCAP, and a touch layer.

The substrate SUB may include a first substrate SUB1, a substrate insulating film IPD, and a second substrate SUB2. The substrate insulating film IPD may be located between the first substrate SUB1 and the second substrate SUB2.

The moisture penetration may be prevented by configuring the substrate SUB with a first substrate SUB1, a substrate insulating film IPD, and a second substrate SUB2.

For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

Various patterns (e.g., ACT, SD1 and GATE), various insulating films (e.g., MBUF, ABUF1, ABUF2, GI, ILD1, ILD2 and PAS0), and various metal patterns (e.g., TM, GM, ML1 and ML2) for forming transistors such as a driving transistor DRT may be disposed on the substrate SUB.

A multi-buffer layer MBUF may be disposed on the second substrate SUB2, and a first active buffer layer ABUF1 may be disposed on the multi-buffer layer MBUF.

A first metal layer ML1 and a second metal layer ML2 may be disposed on the first active buffer layer ABUF1. Here, the first metal layer ML1 and the second metal layer ML2 may be a light shield layer LS for shielding the light.

A second active buffer layer ABUF2 may be disposed on the first metal layer ML1 and the second metal layer ML2. An active layer ACT of a driving transistor DRT may be disposed on the second active buffer layer ABUF2.

A gate insulating film GI may be disposed so as to cover the active layer ACT.

A gate electrode GATE of a driving transistor DRT may be disposed on the gate insulating film GI. In this case, at a position different from the formation position of the driving transistor DRT, a gate material layer GM may be disposed on the gate insulating film GI together with the gate electrode GATE of the driving transistor DRT.

A first interlayer insulating film ILD1 may be disposed so as to cover the gate electrode GATE and the gate material layer GM. A metal pattern TM may be disposed on the first interlayer insulating film ILD1. The metal pattern TM may be located at a position different from the formation position of the driving transistor DRT.

A second interlayer insulating film ILD2 may be disposed on the first interlayer insulating film ILD1 so as to cover the metal pattern TM.

Two first source-drain electrode patterns SD1 may be disposed on the second interlayer insulating film ILD2. One of the two first source-drain electrode patterns SD1 is a source node of a driving transistor DRT, and the other is a drain node of the driving transistor DRT.

The two first source-drain electrode patterns SD1 may be electrically connected to one side and the other side of the active layer ACT, respectively, through contact holes of the second interlayer insulating film ILD2, the first interlayer insulating film ILD1, and the gate insulating film GI.

Meanwhile, the second interlayer insulating film ILD2 may include a second-1 interlayer insulating film ILD2-1 and a second-2 interlayer insulating film ILD2-2. The second-1 interlayer insulating film ILD2-1 may be disposed so as to cover the metal pattern TM. The second-2 interlayer insulating film ILD2-2 may be positioned on the second-1 interlayer insulating film ILD2-1.

A portion of the active layer ACT overlapping with the gate electrode GATE may be a channel area. One of the two first source-drain electrode patterns SD1 may be connected to one side of the channel area in the active layer ACT, and the other of the two first source-drain electrode patterns SD1 may be connected to the other side of the channel area in the active layer ACT.

A passivation layer PAS0 may be disposed so as to cover the two first source-drain electrode patterns SD1. A planarization layer PLN may be disposed on the passivation layer PAS0.

The planarization layer PLN may include a first planarization layer PLN1 and a second planarization layer PLN2. The planarization layer PLN may be formed of an organic insulating material such as an acrylic resin.

The first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SD1 (corresponding to the drain electrode N3 of the driving transistor DRT in the subpixel SP of FIG. 2) through a contact hole of the first planarization layer PLN1.

The second planarization layer PLN2 may be disposed so as to cover the second source-drain electrode pattern SD2. A light emitting element ED may be disposed on the second planarization layer PLN2.

The light emitting element ED may include an anode electrode AE, an emission layer EL, and a cathode electrode CE.

The anode electrode AE may be disposed on the second planarization layer PLN2. The anode electrode AE may be electrically connected to the second source-drain electrode pattern SD2 through a contact hole of the second planarization layer PLN2.

The bank BANK may be disposed so as to cover a part of the anode electrode AE. A part of the bank BANK corresponding to the emission area EA of the subpixel SP may be opened or removed.

A part of the anode electrode AE may be exposed to an opening (or open portion) of the bank BANK.

An emission layer EL may be located on the side of the bank BANK and the opening (or open portion) of the bank BANK. All or part of the emission layer EL may be located between adjacent banks BANK. The emission layer EL may include an organic film.

In the opening of the bank BANK, the emission layer EL may be in contact with the anode electrode AE. A cathode electrode CE may be disposed on the emission layer EL.

An encapsulation layer ENCAP may be disposed on the light emitting element ED.

The encapsulation layer ENCAP may have a single-layer structure or a multi-layer structure. For example, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic films, and the second encapsulation layer PCL may be an organic film. Among the first encapsulation layer PAS1, the second encapsulation layer PCL, and the third encapsulation layer PAS2, the second encapsulation layer PCL may be the thickest. Accordingly, the second encapsulation layer PCL may function as a planarization layer.

The first encapsulation layer PAS1 may also be referred to as a first inorganic encapsulation layer, the second encapsulation layer PCL may also be referred to as an organic encapsulation layer, and the third encapsulation layer PAS2 may also be referred to as a second inorganic encapsulation layer.

The first encapsulation layer PAS1 may be disposed on the cathode electrode CE and may be disposed closest to the light emitting element ED. The first encapsulation layer PAS1 may be formed of an inorganic insulating material capable of low-temperature deposition. For example, the first encapsulation layer PAS1 may be silicon nitride (SiNₓ), silicon oxide (SiOₓ), silicon oxynitride (SiON), or aluminum oxide (Al₂O₃). Since the first encapsulation layer PAS1 is deposited in a low-temperature atmosphere, the first encapsulation layer PAS1 may prevent the emission layer EL including an organic material vulnerable to a high-temperature atmosphere from being damaged during the deposition process.

The second encapsulation layer PCL may be formed with a smaller area than the first encapsulation layer PAS1. In this case, the second encapsulation layer PCL may be formed to expose both ends of the first encapsulation layer PAS1. The second encapsulating layer PCL may act as a buffer to relieve stress between each layer due to bending of the display device 100 and may also serve to enhance flattening performance.

For example, the second encapsulation layer PCL may be formed of an acrylic resin, an epoxy resin, a polyimide, polyethylene, or silicon oxycarbon (SiOC), and may be formed of an organic insulating material. For example, the second encapsulation layer PCL may be formed through an inkjet method.

The third encapsulation layer PAS2 may be formed on the second encapsulation layer PCL to cover the upper surface and side surfaces of each of the second encapsulation layer PCL and the first encapsulation layer PAS1. The third encapsulation layer PAS2 may minimize or block external moisture or oxygen from penetrating into the first encapsulation layer PAS1 and the second encapsulation layer PCL.

For example, the third encapsulation layer PAS2 may be formed of an inorganic insulating material such as silicon nitride (SiNₓ), silicon oxide (SiOₓ), silicon oxynitride (SiON), or aluminum oxide (Al₂O₃).

Meanwhile, the display device 100 of the present disclosure may have a touch sensor TS formed on the encapsulation layer ENCAP to detect a touch of a user's finger or pen.

If the touch sensor TS is of a type built into the display panel 110, the touch sensor TS may be disposed on the encapsulation layer ENCAP. It will be described the touch sensor structure in detail as follows.

A touch buffer film T-BUF may be disposed on the encapsulation layer ENCAP.

A touch sensor TS may be disposed on the touch buffer film T-BUF.

The touch sensor TS may include a touch sensor metal TSM and a bridge metal BRG positioned in different layers.

The touch sensor metal TSM and the bridge metal BRG may be formed of a triple structure of Ti/Al/Ti.

A touch interlayer insulating film T-ILD may be disposed between the touch sensor metal TSM and the bridge metal BRG.

The touch interlayer insulating film T-ILD may be formed of an inorganic material such as silicon nitride (SiNx) or silicon oxide (SiOx). In this case, the touch interlayer insulating film T-ILD may be formed of an inorganic material such as silicon oxide (SiOx) to improve touch performance.

For example, the touch sensor TS may include a first touch sensor metal, a second touch sensor metal, and a third touch sensor metal that are positioned adjacent to each other.

If a third touch sensor metal is present between the first touch sensor metal and the second touch sensor metal, and the first touch sensor metal and the second touch sensor metal are to be electrically connected to each other, the first touch sensor metal and the second touch sensor metal may be electrically connected to each other through a bridge metal BRG in a different layer.

The bridge metal BRG may be insulated from the third touch sensor metal by a touch interlayer insulating film T-ILD.

When a touch sensor TS is formed on a display panel 110, a chemical solution (e.g., developer solution or etchant, etc.) used in the process or moisture may be generated from the outside.

Since the touch sensor TS is disposed on a touch buffer film T-BUF, the chemical solution or moisture may be prevented from penetrating into the emission layer EL including an organic substance during the manufacturing process of the touch sensor TS.

Accordingly, the touch buffer film T-BUF may prevent damage to the emission layer EL that is vulnerable to liquid or moisture.

The touch buffer film T-BUF may be formed at a low temperature (e.g., 100° C.) or lower, and may be formed of an organic insulating material having a low dielectric constant in order to prevent damage to the emission layer EL including an organic material vulnerable to high temperatures. For example, the touch buffer film T-BUF may be formed of an acrylic series, an epoxy series, or a siloxane series material.

If the display device 100 is bent, the encapsulation layer ENCAP may be damaged due to bending, and the touch sensor metal TSM located on the touch buffer film T-BUF may be broken. Even if the display device 100 is bent, the encapsulation layer ENCAP may be prevented from being damaged or the touch sensor metal TSM or bridge metal BRG may be prevented from being broken by the touch buffer film T-BUF having flattening performance using an organic insulating material.

A protection layer PAC may be disposed so as to cover the touch sensor TS. The protective layer PAC can be an organic insulating film.

Meanwhile, in the process of forming the display panel 110 into a thin film, if the thickness of the second encapsulation layer PCL, which corresponds to the organic encapsulation layer, becomes smaller than a reference thickness, the second encapsulation layer PCL may not be properly applied on the upper portion of the light emitting element ED, which may cause the light emitting element ED to be exposed to the outside or moisture enter the display panel.

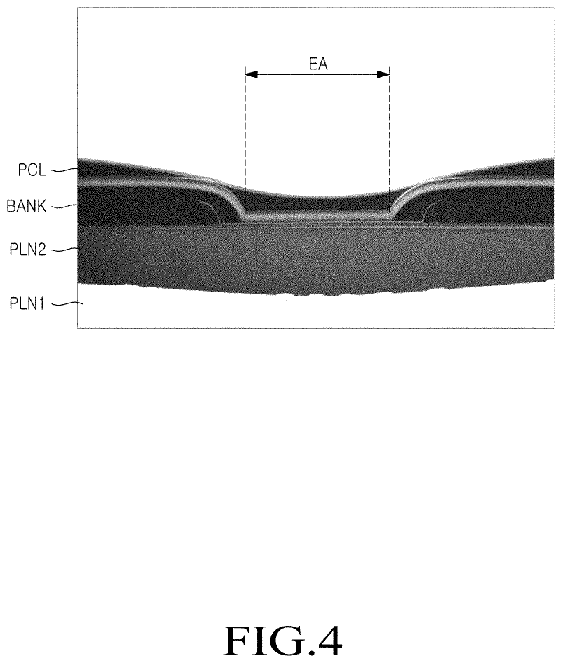

FIG. 4 is an example of a cross-sectional photograph of an encapsulation layer formed on the upper part of a bank in a display device.

Referring to FIG. 4, the display device may open a portion of a bank BANK located on the upper part of the planarization layer PLN1 and PLN2, and form an emission area EA where the light emitting element ED is located.

In a state where the emission area EA is formed, an encapsulation layer may be formed to cover the emission area EA and the bank BANK. The encapsulation layer may be formed as a laminated structure in which an organic encapsulation layer is disposed between inorganic encapsulation layers. Here, only the organic encapsulation layer PCL is shown.

The organic encapsulation layer PCL may be formed with various thicknesses. In this case, if the organic encapsulation layer PCL is formed below a reference thickness, the emission area EA may not be properly covered.

In this case, the light emitting element located in the emission area EA may be exposed to the outside or external moisture may enter, resulting in a defect.

Therefore, even if the thickness of the organic encapsulation layer PCL is thinned, it is necessary to form a structure in which the organic encapsulation layer PCL is properly applied on the light emitting element ED.

This problem mainly occurs in the case of the organic encapsulation layer PCL, but may also occur in the process of forming the inorganic encapsulation layer PAS. Therefore, the following description focuses on the structure in which the organic encapsulation layer PCL is applied, but it can also be applied to cases where the inorganic encapsulation layer PAS is not properly applied to the emission area EA.

The display device 100 of the present disclosure may form a bank BANK located below the encapsulation layer ENCAP with a double pattern structure so that the encapsulation layer ENCAP (particularly, the organic encapsulation layer PCL) can be properly applied along the emission area EA.

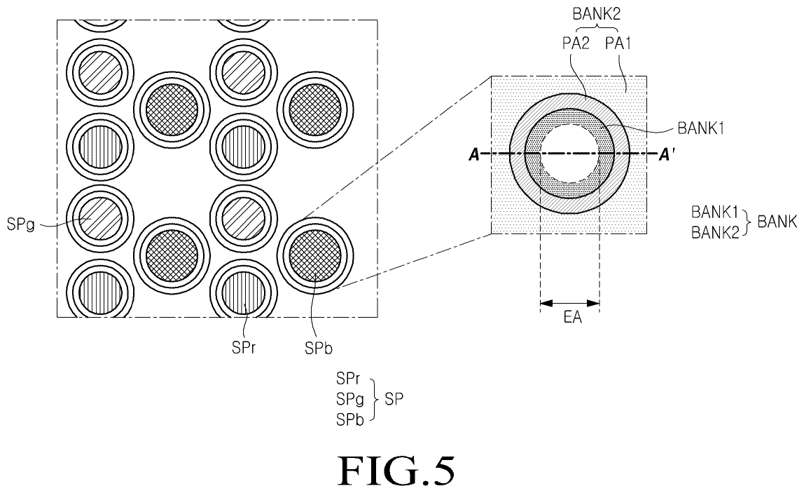

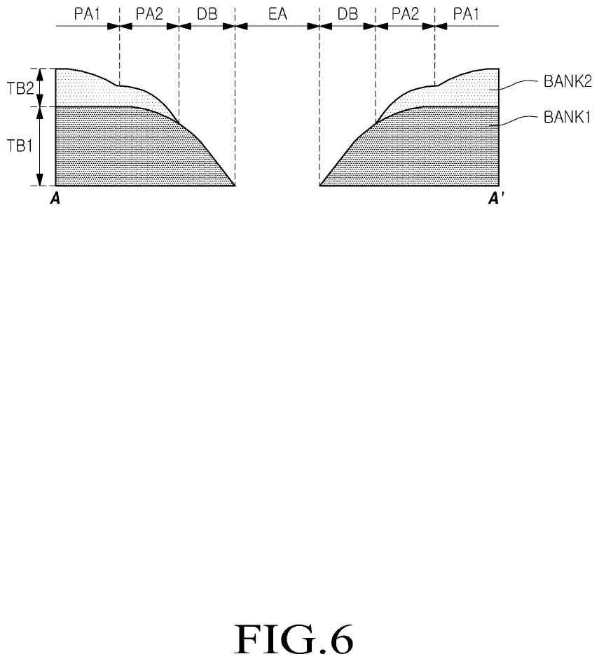

FIG. 5 is a plan view of a case in which a bank located around the emission area is formed with a double pattern structure in a display device according to embodiments of the present disclosure. In addition, FIG. 6 is a cross-sectional view of a subpixel including a bank of a double pattern structure, taken along the A-A′ direction.

Referring to FIGS. 5 and 6, in the display device 100 according to the embodiments of the present disclosure (FIG. 1), a display area DA of a display panel 110 may have subpixels that emit a plurality of colors.

For example, the display area DA of the display panel 110 may include a red subpixel SPr that emits a red color, a green subpixel SPg that emits a green color, and a blue subpixel SPb that emits a blue color.

Each subpixel SP may emit a color specified by a light emitting element ED formed in the emission area EA, and a bank BANK may be formed around the emission area EA to define the emission area EA.

In this case, the display device 100 of the present disclosure (FIG. 1) may form a bank BANK with a structure in which a first bank BANK1 and a second bank BANK2 are stacked to define an emission area EA.

The first bank BANK1 may be formed with a first bank thickness TB1 on the planarization layer PLN to define an emission area EA.

The first bank BANK1 may include a black pigment, and may be made of an organic material or an inorganic material.

The second bank BANK2 may be formed with a second bank thickness TB2 on the first bank BANK1. The second bank thickness TB2 may be smaller than the first bank thickness TB1. For example, the second bank thickness TB2 of the second bank BANK2 may be 1 μm or less, and the first bank thickness TB1 of the first bank BANK1 may be 1 to 2 μm.

The second bank BANK2 may be formed spaced apart from the emission area EA by a bank separation distance DB. The bank separation distance DB may be 1 to 5 μm.

The second bank BANK2 may include a first pattern area PA1 and a second pattern area PA2 formed with different thicknesses on the first bank BANK1.

The first pattern area PA1 of the second bank BANK2 may be an area forming a second bank thickness TB2 of the second bank BANK2, and the second pattern area PA2 may be formed lower than the second bank thickness TB2 and positioned adjacent to the emission area EA.

The second pattern area PA2 may be disposed in a circular shape along the shape of the emission area EA at the outer edge of the emission area EA.

The second pattern area PA2 may be formed by a half-tone mask in the process of forming the emission area EA by a full-tone mask.

Accordingly, the second bank BANK2 may be referred to have a step structure including the first pattern area PA1 and the second pattern area PA2.

The second bank BANK2 may be formed of a transparent material, and the transparent material forming the second bank BANK2 may be one of polyimide, photo acryl, and benzocyclobutene (BCB).

In the second bank BANK2, the second pattern area PA2 may be formed between the emission area EA and the first pattern area PA1.

In the second bank BANK2, the thickness of the second pattern area PA2 may be smaller than the thickness of the first pattern area PA1.

Therefore, the encapsulation layer ENCAP, particularly the organic encapsulation layer PCL, formed on the second bank BANK2 can be easily formed to cover the emission area EA since a material for the encapsulation layer is easy to flow down from the first pattern area PA1 to the second pattern area PA2 at a low position.

In this case, even if the organic encapsulation layer PCL is formed to be 10 μm or less, the encapsulation layer ENCAP or the organic encapsulation layer PCL may be formed to cover the emission area EA.

Meanwhile, the display device 100 of the present disclosure may form a second bank BANK2 to include a third pattern area PA3 formed as a valley pattern between subpixels SP in order to improve the fluidity of the encapsulation layer ENCAP between subpixels SP.

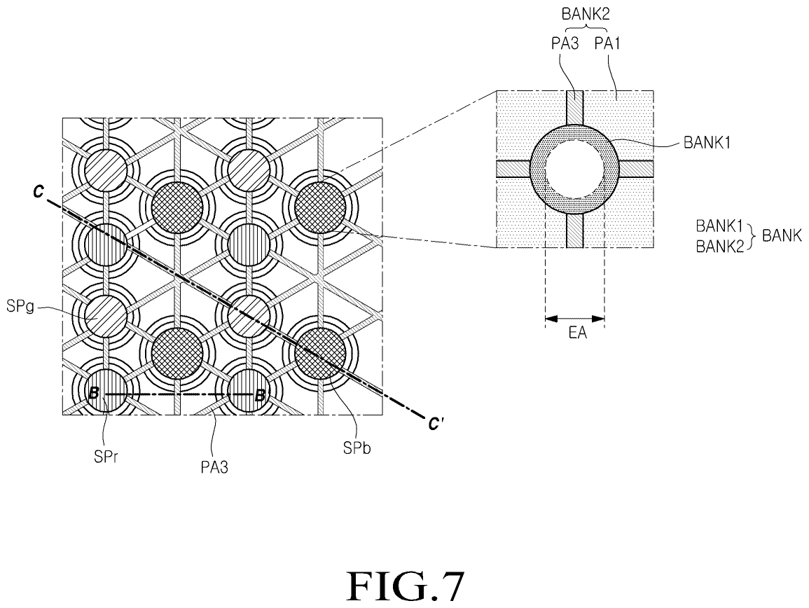

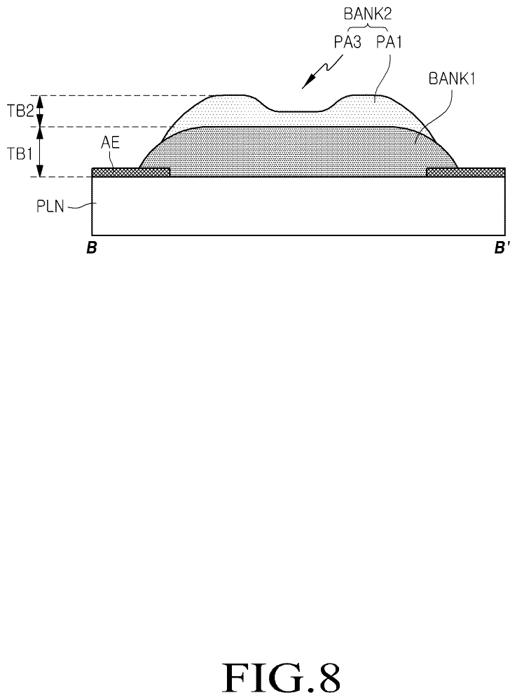

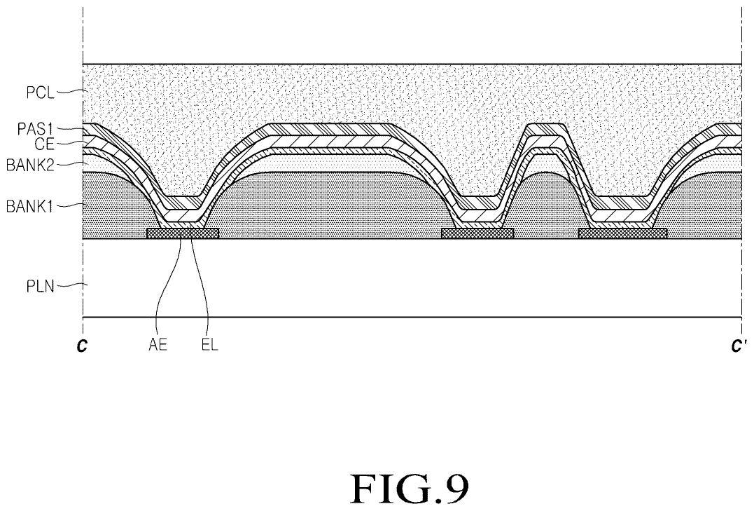

FIG. 7 is a plan view of a bank structure including a valley pattern between subpixels in a display device according to embodiments of the present disclosure. In addition, FIG. 8 is a cross-sectional view of the bank structure including the valley pattern cut in the B-B′ direction, and FIG. 9 is a cross-sectional view of the bank structure including the valley pattern cut in the C-C′ direction.

Referring to FIGS. 7 to 9, in the display device 100 according to embodiments of the present disclosure (FIG. 1), subpixels emitting a plurality of colors may be arranged in the display area DA of the display panel 110.

Each subpixel SP may emit a color specified by a light emitting element ED formed in an emission area EA, and a bank BANK may be formed around the emission area EA to define the emission area EA.

In this case, the display device 100 of the present disclosure (FIG. 1) may include a first bank BANK1 for defining the emission area EA and a second bank BANK2 formed on the first bank BANK1 around the first bank BANK1.

The first bank BANK1 may be formed on the upper portion of the planarization layer PLN with a first bank thickness TB1 to define the emission area EA.

The first bank BANK1 may include a black pigment, and may be made of an organic material or an inorganic material.

The second bank BANK2 may be formed with a second bank thickness TB2 on the first bank BANK1. The second bank thickness TB2 may be smaller than the first bank thickness TB1. For example, the second bank thickness TB2 of the second bank BANK2 may be 1 μm or less, and the first bank thickness TB1 of the first bank BANK1 may be 1 to 2 μm.

The second bank BANK2 may include a first pattern area PA1 and a third pattern area PA3 formed with different thicknesses on the first bank BANK1.

The first pattern area PA1 of the second bank BANK2 may be an area forming the second bank thickness TB2 of the second bank BANK2, and the third pattern area PA3 may be formed as a valley pattern between the subpixels SP.

The third pattern area PA3 may extend in a straight line structure between the subpixels SP, and may be formed as a valley pattern lower than the second bank thickness TB2 so that the upper encapsulation layer ENCAP, especially the organic encapsulation layer PCL, can be easily spread and applied.

However, it is effective to form the third pattern area PA3 so that the lower first bank BANK1 is not exposed.

The third pattern area PA3 may be formed using a half-tone mask in the process of forming the emission area EA using a full-tone mask.

Accordingly, the second bank BANK2 may be formed with a structure including the first pattern area PA1 and the third pattern area PA3.

The second bank BANK2 may be formed of a transparent material, and the transparent material forming the second bank BANK2 may be one of polyimide, photo acryl, and benzocyclobutene (BCB).

Since the third pattern area PA3 in the second bank BANK2 is formed to have a lower thickness than the first pattern area PA1, the encapsulation layer ENCAP, particularly the organic encapsulation layer PCL, formed on the second bank BANK2 may flow down from the first pattern area PA1 along the third pattern area PA3 at a lower position to effectively cover the emission area EA.

Therefore, even if the organic encapsulation layer PCL is formed to have a thickness of 10 μm or less on the bank BANK, the encapsulation layer ENCAP or the organic encapsulation layer PCL can be formed to cover the emission area EA.

In this case, the third pattern area PA3 of the second bank BANK2 extending between the subpixels SP may be extended to connect the emission area EA of the subpixels SP, or may be extended only to a part of the outer area of the subpixels SP.

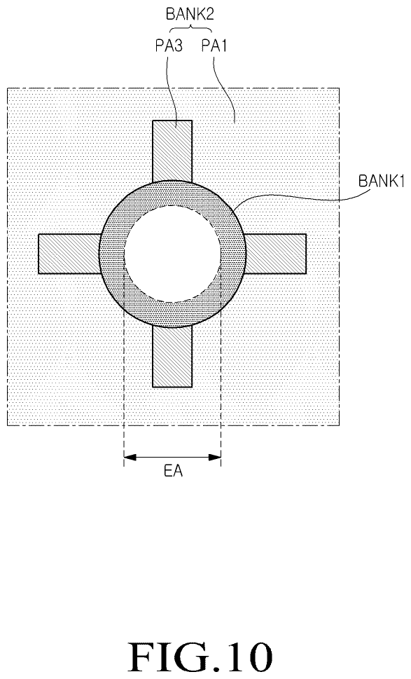

FIG. 10 is a plan view illustrating a case in which the valley pattern of the second bank extends only to a part of the outer area between the subpixels in a display device according to embodiments of the present disclosure.

Referring to FIG. 10, in the display device 100 according to embodiments of the present disclosure (FIG. 1), the third pattern area PA3 of the second bank BANK2 extending between the subpixels SP may be extended only to a part of the outer area of the subpixels SP. In this case, the third pattern area PA3 of the second bank BANK2 may be formed in a structure that is disconnected between the subpixels SP.

In addition, the bank BANK of the display device 100 of the present disclosure may be formed to include a first pattern area PA1 and a second pattern area PA2 around the emission area EA, and a third pattern area PA3 of a valley pattern between the subpixels SP.

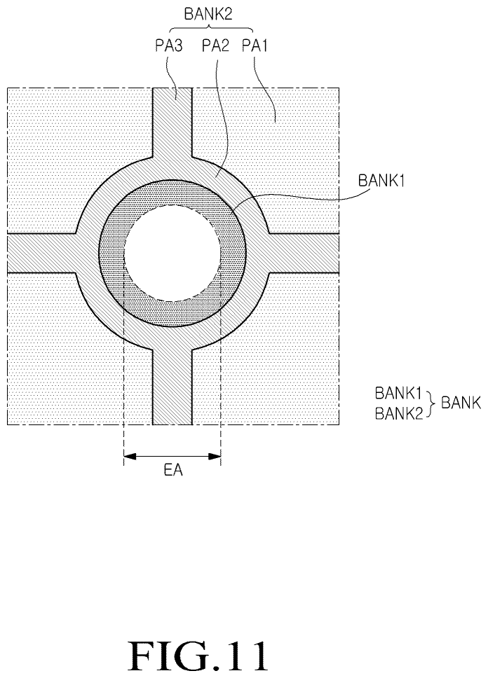

FIG. 11 is a plan view of a bank structure including a double pattern located around the emission area and a valley pattern between the subpixels in the display device according to embodiments of the present disclosure.

Referring to FIG. 11, the display device 100 according to the embodiments of the present disclosure (FIG. 1) may form a bank BANK positioned below an encapsulation layer ENCAP as a stacked structure of a first bank BANK1 and a second bank BANK2, and may form a second bank BANK2 around an emission area EA as a double pattern structure of a first pattern area PA1 and a second pattern area PA2.

As a result, the encapsulation layer ENCAP, particularly the organic encapsulation layer PCL formed on the second bank BANK2, can easily flow down from the first pattern area PA1 to the second pattern area PA2 at a low position, so that the emission area EA can be easily applied.

In addition, the display device 100 of the present disclosure (FIG. 1) may easily apply the encapsulation layer ENCAP between the subpixels SP by including a third pattern area PA3 formed as a valley pattern between the subpixels SP in order to improve the fluidity of the encapsulation layer ENCAP between the subpixels SP.

In addition, the display device 100 of the present disclosure (FIG. 1) may form a convex portion at a position where the third pattern areas PA3 of the valley pattern overlap, thereby allowing the encapsulation layer ENCAP, particularly the organic encapsulation layer PCL, to flow more effectively along the third pattern area PA3.

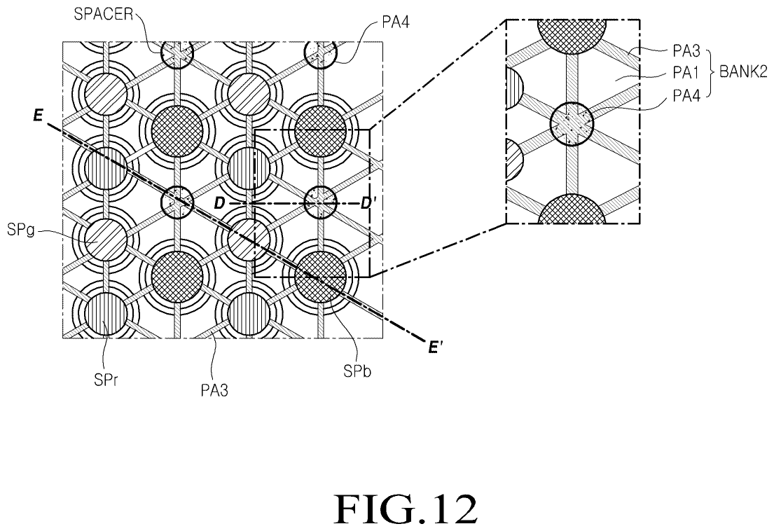

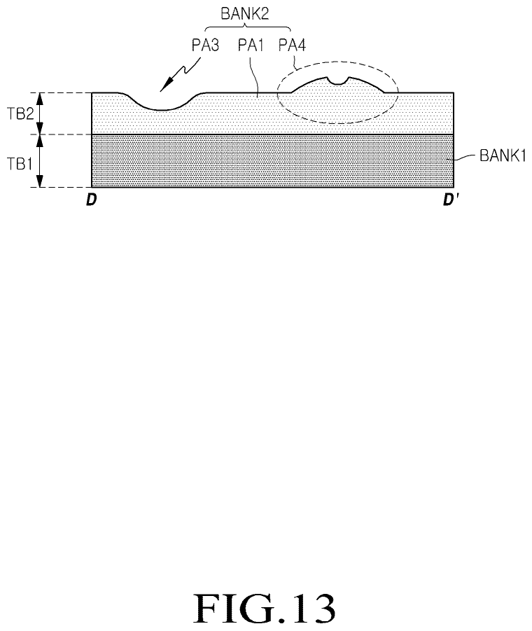

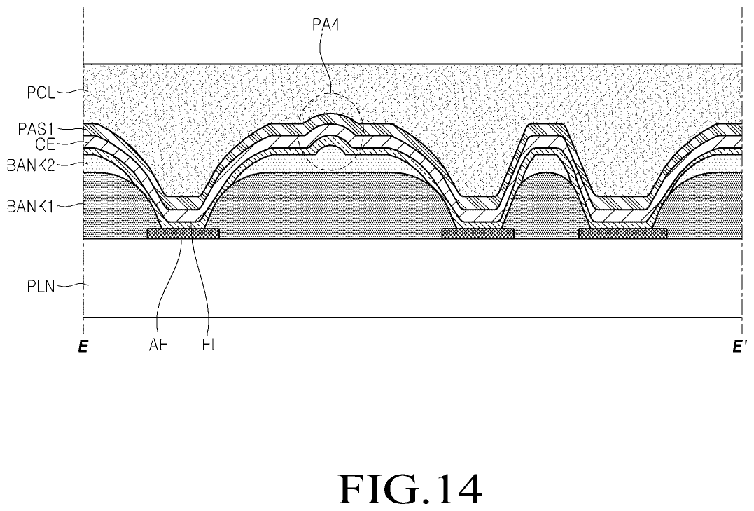

FIG. 12 is a plan view of a bank structure including a convex portion between subpixels in a display device according to embodiments of the present disclosure. In addition, FIG. 13 is a cross-sectional view of a bank structure including a convex portion cut in the D-D′ direction, and FIG. 14 is a cross-sectional view of a bank structure including a convex portion cut in the E-E′ direction.

Referring to FIGS. 12 to 14, in a display device 100 according to embodiments of the present disclosure (FIG. 1), a display area DA of a display panel 110 may have subpixels emitting a plurality of colors.

Each subpixel SP may emit a color specified by a light emitting element ED formed in an emission area EA, and a bank BANK may be formed around the emission area EA to define the emission area EA.

In this case, the display device 100 (FIG. 1) of the present disclosure may include a first bank BANK1 for defining an emission area EA and a second bank BANK2 formed on the first bank BANK1 around the first bank BANK1.

The first bank BANK1 may be formed with a first bank thickness TB1 on a planarization layer PLN to define an emission area EA.

The first bank BANK1 may include a black pigment and may be made of an organic material or an inorganic material.

The second bank BANK2 may be formed of a transparent material, and the transparent material forming the second bank BANK2 may be one of polyimide, photo acryl, and benzocyclobutene (BCB).

The second bank BANK2 may include a transparent material formed with a second bank thickness TB2 on the first bank BANK1. The second bank thickness TB2 may be smaller than the first bank thickness TB1. For example, the second bank thickness TB2 of the second bank BANK2 may be 1 μm or less, and the first bank thickness TB1 of the first bank BANK1 may be 1 to 2 μm.

The second bank BANK2 may include a first pattern area PA1 and a third pattern area PA3.

The first pattern area PA1 of the second bank BANK2 may be an area forming a second bank thickness TB2, and the third pattern area PA3 may be formed as a valley pattern between subpixels SP.

The third pattern area PA3 may extend in a straight line structure between the subpixels SP so that the upper encapsulation layer ENCAP, particularly the organic encapsulation layer PCL, may be easily spread and applied.

The third pattern area PA3 may be formed using a half-tone mask in the process of forming the emission area EA using a full-tone mask.

In this case, since the third pattern area PA3 extends between the subpixels SP, there may be formed an area where the third pattern areas PA3 overlap with each other.

The display device 100 of the present disclosure may form a fourth pattern area PA4 including a convex portion at a location where the third pattern areas PA3 overlap, thereby allowing the encapsulation layer ENCAP to spread well along the third pattern area PA3.

The fourth pattern area PA4 may include a protruding structure that protrudes above the second bank thickness TB2. In addition, the fourth pattern area PA4 may include a concave portion that is partially sunken at the top of the protruding structure.

In this case, a bottom of the concave portion may be formed at a position higher than the second bank thickness TB2.

Meanwhile, a spacer SPACER may be formed in some areas between subpixels SP. Accordingly, the fourth pattern area PA4 including the convex portion may be located in an area where the spacer SPACER is not formed.

In this case, the spacer SPACER may be formed higher than the fourth pattern area PA4. Accordingly, in the process of depositing a protective film such as an overcoat layer on the upper portion, contact between the mask and the display panel 110 may be minimized and the fourth pattern area PA4 may be prevented from contacting the mask.

In this way, in the display device 100 of the present disclosure (FIG. 1), the fourth pattern area PA4 constituting the second bank BANK2 may be formed at a higher position than the first pattern area PA1, and the third pattern area PA3 may be formed at a lower position than the first pattern area PA1. Therefore, the encapsulation layer ENCAP, particularly the organic encapsulation layer PCL, formed on the second bank BANK2 can easily flow down from the fourth pattern area PA4 along the first pattern area PA1 and the third pattern area PA3 to effectively cover the emission area EA.

Therefore, even if the organic encapsulation layer PCL is formed to be 10 μm or less on the bank BANK, the encapsulation layer ENCAP or the organic encapsulation layer PCL can be formed to cover the emission area EA.

The embodiments of the present disclosure described above are summarized as follows.

A display device according to the embodiments of the present disclosure may include a display panel including a display area in which a plurality of subpixels are disposed, and a driving circuit configured to drive the display panel. The display area may include a first bank defining an emission area of the plurality of subpixels, and a second bank including multi-pattern areas of different thicknesses on the first bank.

The first bank may include a black pigment formed in a first bank thickness.

The second bank may be a transparent bank formed with a second bank thickness smaller than the first bank thickness.

The first bank thickness may be 1 to 2 μm, and the second bank thickness may be 1 μm or less.

The multi-pattern area may include a first pattern area formed with a second bank thickness, and a second pattern area with a thickness smaller than the second bank thickness between the first pattern area and an emission area.

The second pattern area may be located between the first pattern area and the emission area.

The second pattern area may be formed along an outer side of the emission area with the same shape as the emission area.

A separation distance between the emission area and the second pattern area may be 1 to 5 μm.

The multi-pattern area may further include a third pattern area formed as a valley pattern between a plurality of subpixels.

The multi-pattern area may include a first pattern area formed with a second bank thickness, and a third pattern area formed as a valley pattern between a plurality of subpixels.

The third pattern area may extend to connect the plurality of subpixels.

A depth of the third pattern area may be smaller than the second bank thickness.

The third pattern area may be located in at least some area between adjacent subpixels.

The multi-pattern area may further include a fourth pattern area including a convex portion at a position where the third pattern areas overlap.

The fourth pattern area may be formed in an area where a spacer is not located.

The fourth pattern area may be formed lower than the spacer.

The fourth pattern area may include a convex portion protruding upwardly, and a concave portion partially sunken at the top of the convex portion.

The concave portion may include a bottom formed at a position higher than a second bank thickness.

The display panel may further include an encapsulation layer formed on the second bank. The encapsulation layer may include a first inorganic encapsulating layer, an organic encapsulating layer formed on the first inorganic encapsulating layer with a thickness of 10 μm or less, and a second inorganic encapsulating layer formed on the organic encapsulating layer.

A display panel according to embodiments of the present disclosure may include a plurality of subpixels, a first bank defining an emission area of the plurality of subpixels, and a second bank including multi-pattern areas of different thicknesses on the first bank.

The display panel according to embodiments of the present disclosure may further include an encapsulation layer formed on the second bank. The encapsulation layer may include a first inorganic encapsulating layer, an organic encapsulating layer formed on the first inorganic encapsulating layer with a thickness of 10 μm or less, and a second inorganic encapsulating layer formed on the organic encapsulating layer.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the pr sent invention. The above description and the accompanying drawings provide an example of the technical idea of the present invention for illustrative purposes only. That is, the disclosed embodiments are intended to illustrate the scope of the technical idea of the present invention.

What is claimed is:

1. A display device comprising:
a display panel comprising a display area in which a plurality of subpixels are disposed; and
a driving circuit configured to drive the display panel,
wherein the display area comprises a first bank for defining an emission area of the plurality of subpixels, and a second bank formed on the first bank,
wherein the second bank comprises a first pattern area and a second pattern area, and
wherein a thickness of the second pattern area is smaller than a thickness of the first pattern area.

2. The display device of claim 1, wherein the first bank comprises a black pigment with a first bank thickness.

3. The display device of claim 2, wherein the second bank is a transparent bank, and wherein a second bank thickness is smaller than the first bank thickness.

4. The display device of claim 3, wherein the first bank thickness is from 1 to 2 μm, and wherein the second bank thickness is 1 μm or less.

5. The display device of claim 1, wherein the second pattern area is located between the first pattern area and the emission area.

6. The display device of claim 5, wherein the second pattern area is formed along an outer side of the emission area with the same shape as the emission area.

7. The display device of claim 6, wherein the second pattern area is spaced apart from the emission area by a separation distance.

8. The display device of claim 7, wherein the separation distance between the emission area and the second pattern area is from 1 to 5 μm.

9. The display device of claim 3, wherein the second bank further comprises a third pattern area consisting of at least one valley pattern between the plurality of subpixels.

10. The display device of claim 9, wherein the third pattern area extends to connect the plurality of subpixels.

11. The display device of claim 10, wherein a depth of the third pattern area is smaller than the second bank thickness.

12. The display device of claim 9, wherein the third pattern area is located in at least some area between adjacent subpixels.

13. The display device of claim 9, wherein the second bank further comprises a fourth pattern area comprising a convex portion at a position where the third pattern areas overlap.

14. The display device of claim 13, wherein the fourth pattern area is formed in an area where a spacer is not located.

15. The display device of claim 14, wherein the fourth pattern area is formed lower than the spacer.

16. The display device of claim 13, wherein the fourth pattern area comprises a concave portion that is partially sunken at the top of the convex portion.

17. The display device of claim 16, wherein the concave portion comprises a bottom formed at a position higher than the second bank thickness.

18. The display device of claim 1, wherein the display panel further comprises an encapsulation layer formed on the second bank,
wherein the encapsulation layer comprises:
a first inorganic encapsulating layer;
an organic encapsulating layer formed on the first inorganic encapsulating layer with a thickness of 10 μm or less; and
a second inorganic encapsulating layer formed on the organic encapsulating layer.

19. A display panel comprising:
a plurality of subpixels;
a first bank defining an emission area of the plurality of subpixels; and
a second bank formed on the first bank,
wherein the second bank comprises a first pattern area and a second pattern area, and
wherein a thickness of the second pattern area is smaller than a thickness of the first pattern area.

20. The display panel of claim 19, further comprising an encapsulation layer formed on the second bank,
wherein the encapsulation layer comprises:
a first inorganic encapsulating layer;
an organic encapsulating layer formed on the first inorganic encapsulating layer with a thickness of 10 μm or less; and
a second inorganic encapsulating layer formed on the organic encapsulating layer.
